(19) United States
(12) Patent Application Publication
(10) Pub. No.: US 2011/0042718 A1
(43) Pub. Date: Feb. 24, 2011

(54) NITRIDE SEMICONDUCTOR LAYER-CONTAINING STRUCTURE, NITRIDE SEMICONDUCTOR LAYER-CONTAINING COMPOSITE SUBSTRATE AND PRODUCTION METHODS OF THESE

(75) Inventors: Shinan Wang, Kashiwa-shi (JP); Kenji Tamamori, Ebina-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/922,892

(22) PCT Filed: May 25, 2009
(86) PCT No.: PCT/JP2009/059919

§ 371 Date: Sep. 16, 2010

(30) Foreign Application Priority Data
May 26, 2008 (JP) 2008-136290

(51) Int. Cl. H01L 21/20; H01L 29/20

(52) U.S. Cl. 257/190; 438/479; 438/481; 257/E21.126; 257/E29.089

(57) ABSTRACT

A nitride semiconductor layer-containing structure having a configuration in which: the structure includes a laminated structure based on at least two nitride semiconductor layers; the structure includes between the two nitride semiconductor layers in the laminated structure a plurality of voids surrounded by the faces of the walls inclusive of the inner walls of the recessed portions of the asperity pattern formed on the nitride semiconductor layer that is the lower layer of the two nitride semiconductor layers; and crystallinity defect-containing portions to suppress the lateral growth of the nitride semiconductor layer are formed on at least part of the inner walls of the recessed portions to form the voids.

### TECHNICAL FIELD

The present invention relates to a nitride semiconductor layer-containing structure, a nitride semiconductor layer-containing composite substrate and production methods of these. In particular, the present invention relates to a production method of a nitride semiconductor layer based on an epitaxial lateral over growth.

### BACKGROUND ART

A nitride semiconductor, for example, a gallium nitride compound semiconductor represented by a general formula AlₓGa_{y}In_{1-x-y}N (0≦x≦1, 0≦y≦1, 0≦x+y≦1) has a relatively large band gap and is a direct transition type semiconductor material.

Accordingly, nitride semiconductors attract attention as the materials for forming semiconductor light emitting devices such as a semiconductor laser capable of emitting short wavelength light corresponding to from ultraviolet light to green light, and a light emitting diode (LED) capable of covering a wide emission wavelength range from ultraviolet light to red light and additionally white light.

For the purpose of obtaining high-quality semiconductor light emitting devices, high-quality nitride semiconductor films or substrates are needed.

In particular, for the purpose of obtaining high-quality nitride semiconductor films, it is preferable to conduct epitaxial growth that uses homogeneous high-quality nitride semiconductor substrates, or heterogeneous substrates relatively small in differences of lattice constants and in difference of coefficient of thermal expansion.

Additionally, in the application of nitride semiconductors, it is necessary to remove a base substrate after a nitride semiconductor film or a nitride semiconductor structure has been formed, as the case may be.

However, there has hitherto been a problem that it is difficult to produce high-quality nitride semiconductor films or high-quality nitride semiconductor substrates. The main causes for this problem are described as follows.

(1) The production process of the nitride semiconductor substrate involves high-cost steps. For example, in the production of a GaN substrate, a high temperature and a high pressure are required, and it is difficult to produce a substrate low in defect density and large in caliber. Accordingly, GaN substrates are high in price, and the stationary supply of GaN substrates to meet mass production is not available.

(2) The heterogeneous substrates suitable for the epitaxial growth of the high-quality nitride semiconductor films are scarce. The crystal growth of the nitride semiconductor film is required to be conducted at a high temperature of about 1000° C. and under a strongly corrosive ammonia atmosphere that contains a Group V material. The heterogeneous single crystal substrates capable of withstanding such harsh conditions are limited.

(3) Depending on the devices, complicated structures are required due to the crystal properties of the nitride semiconductor itself. For example, in order to realize an optical element, nitride semiconductors different in composition from each other are required to be laminated in a plurality of layers.

Because of the reasons as described above, sapphire substrates are often adopted as the base substrates of the nitride semiconductors from comprehensive evaluation.

On the other hand, the nitride semiconductors such as GaN, AlGaN and GaInN are totally strained materials different from each other in lattice constants, and hence cracking and stress strain tend to occur between these nitride semiconductors and between these nitride semiconductors and the substrates.

Accordingly, when a heterogeneous substrate such as a sapphire substrate is used, there occurs a problem caused by the dislocation propagating in the nitride semiconductor film due to the lattice constant difference between the nitride semiconductor film and the heterogeneous substrate.

Such a dislocation threads through the nitride semiconductor film to reach the uppermost layer of the nitride semiconductor film to become a threading dislocation, and degrades the properties of the nitride semiconductor film, as the case may be.

Additionally, there is also a problem that a stress strain occurs in the nitride semiconductor film and the heterogeneous substrate due to the difference of coefficient of thermal expansion between the nitride semiconductor film and the heterogeneous substrate. The stress strain not only deforms the nitride semiconductor film and the heterogeneous substrate, but also offers a factor to degrade the nitride semiconductor film.

For the purpose of reducing such a threading dislocation density, in Appl. Phys. Lett., Vol. 72, No. 16, 20 Apr. 1998, pp. 2014 to 2016, disclosed is a method in which by positively taking advantage of the lateral growth, the epitaxial growth of GaN is conducted.

In this case, in the lateral growth method, which is also referred to as ELOG growth (epitaxial lateral over growth) method, first the areas which facilitate the growth of the nitride semiconductor and the areas which disturb the growth of the nitride semiconductor are alternately formed on a heterogeneous substrate.

And, the nitride semiconductor is selectively grown on the growth-facilitating areas and the nitride semiconductor is grown laterally toward the growth-disturbing areas.

On the growth-disturbing areas, the nitride semiconductor is not grown from the substrate, and the growth-disturbing areas are covered with the nitride semiconductor laterally extending from the nitride semiconductor on the growth-facilitating areas.

Therefore, the dislocation having occurred in the interface between the substrate and the nitride semiconductor hardly appears on the surface.

Consequently, a distribution of the threading dislocation density is formed in the nitride semiconductor layer formed by the lateral growth method.

Specifically, the threading dislocation density remains high on the growth-facilitating areas on the heterogeneous substrate, but the threading dislocation density is reduced on the growth-disturbing areas on the heterogeneous substrate.

According to this technique, it is possible to obtain a nitride semiconductor film which is wholly flat and in some areas of which the threading dislocation density in the vicinity of the surface is relatively low.

This technique is provided with a feature that, by taking advantage of the mask pattern formed on the base substrate, a selective ELOG growth of the nitride semiconductor film is realized.

As the material of the mask pattern, for example, SiO₂ is used. In Jpn. J. Appl. Phys., Vol. 42, Part 2, No. 7B, 15 Jul. 2003, pp. L818 to L820, further disclosed is a technique of forming a two-layer structure of a thick-film nitride semiconductor by an ELOG growth using a SiO₂ mask pattern.

Japanese Patent Application Laid-Open No. 2007-314360 also discloses a selective growth technique of the nitride semiconductor film, using a Mg compound as the material of the mask pattern.

According to this technique, Mg promotes the lateral growth of the nitride semiconductor film, and hence a satisfactory nitride semiconductor film can be efficiently produced.

U.S. Pat. No. 6,335,546 also discloses a selective ELOG growth technique of the nitride semiconductor film, not using any mask pattern.

According to this technique, even if a heterogeneous substrate made of a material such as sapphire is used as the base substrate, it is possible to obtain a nitride semiconductor film flat and low in the threading dislocation density.

This effect has also been verified in J. Light & Vis. Env., Vol. 27, No. 3 (2003), pp. 140 to 145. This technique realizes a selective ELOG growth of the nitride semiconductor film by taking advantage of the asperity pattern formed on the growth surface of the substrate, and is provided with a feature that there are voids between the nitride semiconductor film and the substrate in the recessed portions of the pattern. The presence of the voids alleviates to some extent the stress strain between the nitride semiconductor film and the substrate.

For the purpose of reducing the threading dislocation, U.S. Pat. No. 6,979,584 discloses a technique in which: a first nitride semiconductor is provided with a raised and recessed surface (asperity pattern), and then by taking advantages of, as the nuclei, the top faces and the side faces of the raised portions, the epitaxial longitudinal and lateral over growth of a second nitride semiconductor is conducted; and while the recessed portions are being filled with the nitride semiconductor, the nitride semiconductor is also grown upward.

According to this technique, the propagation of the threading dislocation possessed by the first nitride semiconductor is suppressed in the upper portions of the portions in which the second nitride semiconductor undergoes the epitaxial lateral over growth, and it is possible to form in the filled recessed portions the regions where the threading dislocation is alleviated.

In particular, by repeating the raised and recessed surface formation and the epitaxial longitudinal and lateral over growth, it is possible to expect a further reduction of the threading dislocation. This technique is provided with a feature that voids are formed in the second nitride semiconductor.

On the other hand, also in the removal of the base substrate of the nitride semiconductor, there have hitherto been the problems typified by the long operation time and the damage exerted on the nitride semiconductor. These problems are particularly remarkable when sapphire, which is hard, is used for the base substrate.

Japanese Patent Application Laid-Open No. 2001-176813 discloses a production method of a nitride semiconductor substrate in which it is possible to obtain the nitride semiconductor substrate by satisfactorily removing a heterogeneous substrate such as a sapphire substrate.

According to this technique, it is possible to obtain a nitride semiconductor substrate which is free from flaws and is reduced in dislocation, and is satisfactory in crystallinity and surface conditions.

In this technique, the heterogeneous substrate is removed by decomposing the nitride semiconductor with electromagnetic wave irradiation from the side of the heterogeneous substrate; this technique is provided with a feature that the formation of the voids between the nitride semiconductor and the heterogeneous substrate enables to reduce the damage exerted on the nitride semiconductor by the gas pressure of the generated N₂.

However, the technique disclosed in above mentioned Appl. Phys. Lett., Vol. 72, No. 16, 20 Apr. 1998, pp. 2014 to 2016; Jpn. J. Appl. Phys., Vol. 42, Part 2, No. 7B, 15 Jul. 2003, pp. L818 to L820; or Japanese Patent Application Laid-Open No. 2007-314360 requires the use of a material heterogeneous to the nitride semiconductor as the mask for realization of the selective ELOG growth of the nitride semiconductor film.

Accordingly, this technique offers a problem that in the crystal growth process of the nitride semiconductor film which requires a growth temperature of about 1000° C., the mask material is degraded to adversely affect the nitride semiconductor film.

For example, in the case where the mask material is SiO₂, the components thereof, Si or O₂, and in the case where the mask material is a Mg compound, the components thereof, Mg and others, diffuse into the nitride semiconductor film to adversely affect the quality or the carrier control of the nitride semiconductor film, as the case may be.

On the other hand, the technique disclosed in U.S. Pat. No. 6,335,546 or J. Light & Vis. Env., Vol. 27, No. 3 (2003), pp. 140 to 145 uses an asperity pattern, and thereby overcomes the problem of the use of the heterogeneous material mask and at the same time realizes the alleviation of the stress strain between the nitride semiconductor film and the substrate.

However, just a single layer of the void structure formed between the nitride semiconductor film and the substrate by the use of the asperity pattern provides an insufficient reduction of the threading dislocation and an insufficient alleviation of the stress strain.

Just with such a technique, it is not easy to form two or more layers of voids in intended shapes.

On the other hand, the technique disclosed in U.S. Pat. No. 6,979,584 enables to form two or more layers of voids, but offers a difficulty in ensuring the void size because both of the longitudinal growth and the lateral growth are effected at the same time. Consequently, the effect due to the voids on the alleviation of the stress strain is low.

The technique disclosed in Japanese Patent Application Laid-Open No. 2001-176813 removes the base substrate by decomposing the underlying layer, and the impact due to the removal is transmitted to the nitride semiconductor lying directly on the underlying layer.

For example, the microcracks generated in the underlying layer are transmitted to the nitride semiconductor directly lying on the underlying layer, as the case may be. Consequently, the technique disclosed in Japanese Patent Application Laid-Open No. 2001-176813 by itself hardly avoids the damage exerted on the nitride semiconductor at the time of the removal of the base substrate.

In view of the above-described problems, an object of the present invention is to provide the structure that contains the nitride semiconductor layer reduced in the threading dislocation, the nitride semiconductor layer-containing composite substrate, and the production methods of these. Additionally, another object of the present invention is to provide the production method of the nitride semiconductor layer-containing structure that enables the base substrate removal in which the damage exerted on the nitride semiconductor layer is reduced.

### DISCLOSURE OF THE INVENTION

The present invention provides a nitride semiconductor layer-containing structure that is formed as follows, a nitride semiconductor layer-containing composite substrate and the production methods of these.

The nitride semiconductor layer-containing structure of the present invention is characterized in that: the structure includes a laminated structure based on at least two nitride semiconductor layers; the structure includes between the two nitride semiconductor layers in the laminated structure a plurality of voids surrounded by the faces of the walls inclusive of the inner walls of the recessed portions of the asperity pattern formed on the nitride semiconductor layer that is the lower layer of the two nitride semiconductor layers; and crystallinity defect-containing portions to suppress the lateral growth of the nitride semiconductor layer are formed on at least part of the inner walls of the recessed portions to form the voids.

Additionally, the nitride semiconductor layer-containing composite substrate of the present invention is characterized in that the nitride semiconductor layer-containing structure is formed on a base substrate.

Additionally, the production method of a nitride semiconductor layer-containing composite substrate of the present invention is characterized by including: a first step of forming a first nitride semiconductor layer on a base substrate; a second step of forming an asperity pattern on the first nitride semiconductor layer; a third step of forming crystallinity defect-containing portions, due to a state modified from a single crystal state, on at least part of the inner walls of the recessed portions in the asperity pattern on the first nitride semiconductor layer; and a fourth step of forming a second nitride semiconductor layer on the asperity pattern which is formed on the first nitride semiconductor layer and including the crystallinity defect-containing portions.

Additionally, the production method of a nitride semiconductor layer-containing structure of the present invention is characterized by including: a step of producing a composite substrate by using the production method of a composite substrate according to any one of the above-presented descriptions; and a step of removing a base substrate from the composite substrate produced by the production method.

According to the present invention, there can be realized the structure that contains the nitride semiconductor layer reduced in the threading dislocation, the nitride semiconductor layer-containing composite substrate and the production methods of these.

Additionally, there can be realized the production method of the nitride semiconductor layer-containing structure that enables the base substrate removal in which the damage exerted on the nitride semiconductor layer is reduced.

### BRIEF DESCRIPTION OF THE DRAWING

FIG. 1 is a schematic sectional view for illustrating an example of a nitride semiconductor-containing structure in a first embodiment of the present invention;

FIG. 2 is a view illustrating only a first nitride semiconductor layer, as disassembled, in the nitride semiconductor-containing structure in the first embodiment of the present invention;

FIG. 3 is a schematic sectional view for illustrating an example of a nitride semiconductor-containing composite substrate in a second embodiment of the present invention;

FIG. 4 is a view illustrating only a base substrate, as disassembled, in the nitride semiconductor-containing composite substrate in the second embodiment of the present invention;

FIGS. 5A, 5B, 5C, 5D, 5E and 5F are schematic sectional views for illustrating an example of a production method of a nitride semiconductor-containing composite substrate in a third embodiment of the present invention;

FIGS. 6A, 6B, 6C and 6D are schematic sectional views for illustrating an example of a production method of a nitride semiconductor-containing structure in a fourth embodiment of the present invention; and

FIGS. 7A, 7B, 7C, 7D, 7E, 7F and 7G are schematic sectional views for illustrating an application example of the nitride semiconductor-containing composite substrates described in the embodiments and Examples of the present invention.

### BEST MODES FOR CARRYING OUT THE INVENTION

According to the present invention, as a nitride semiconductor layer-containing structure, the above-described structure can be realized.

In an embodiment of the present invention, the above-described structure can be configured as follows.

In the present embodiment, the nitride semiconductor layer-containing structure is provided with a laminated structure based on at least two nitride semiconductor layers.

The structure includes between the two nitride semiconductor layers in the laminated structure a plurality of voids surrounded by the faces of the walls inclusive of the inner walls of the recessed portions of the asperity pattern formed on the nitride semiconductor layer that is the lower layer of the two nitride semiconductor layers.

Crystallinity defect-containing portions to suppress the epitaxial lateral over growth of the nitride semiconductor layer is formed on at least part of the inner walls of the recessed portions to form the voids.

Thus, owing to the voids, in the lateral growth of the nitride semiconductor layer, the film strain of the nitride semiconductor layer and the stress between the two nitride semiconductor layers are alleviated, and the reduction of the threading dislocation density is attained.

Owing to the crystallinity defect-containing portions, the epitaxial lateral over growth of the nitride semiconductor layer in the recessed portions can be suppressed and the size of the voids can be ensured. The crystallinity defect-containing state as referred to herein means a state, modified from a single crystal state, such as an amorphous state, a porous state or a polycrystalline state.

The nitride semiconductor as referred to herein means a gallium nitride compound semiconductor as represented by a general formula AlₓGa_{y}In_{1-x-y}N (0≦x≦1, 0≦y≦1, 0≦x+y≦1).

The nitride semiconductor layer-containing structure according to the present embodiment enables to realize a structure that contains a nitride semiconductor layer reduced in the threading dislocation density. Consequently, a higher-quality nitride semiconductor optical element is made realizable.

In an embodiment of the present invention, a nitride semiconductor layer-containing composite substrate can be configured as follows.

In the present embodiment, by forming the above-described nitride semiconductor layer-containing structure on a base substrate, the nitride semiconductor layer-containing composite substrate can be configured.

In this case, the nitride semiconductor layer-containing composite substrate can be configured to have, between the base substrate and the nitride semiconductor layer that is the lower layer of the two nitride semiconductor layers, a plurality of voids surrounded by the faces of the walls inclusive of the inner walls of the recessed portions of the asperity pattern formed on the nitride semiconductor layer that is the lower layer.

The nitride semiconductor layer-containing composite substrate can also be configured by adopting as the base substrate a single crystal substrate.

The nitride semiconductor layer-containing composite substrate can also be configured by adopting as the base substrate a base substrate in which, on a single crystal substrate, an intermediate film that is homogeneous or heterogeneous to the single crystal substrate is further formed.

The nitride semiconductor layer-containing composite substrate can be formed by adopting as the material of the single crystal substrate any of a nitride semiconductor, sapphire, silicon (Si) and silicon carbide (SiC).

The above-described nitride semiconductor layer-containing structure according to the present embodiment enables to configure a composite substrate that contains a nitride semiconductor layer reduced in the threading dislocation density, and thereby enables the realization of a substrate for use in the epitaxial growth of a nitride semiconductor being highly satisfactory in quality.

In the embodiment of the present invention, the production method of a nitride semiconductor layer-containing composite substrate can be configured as follows.

The production method of a nitride semiconductor layer-containing composite substrate of the present embodiment includes: a first step of forming a first nitride semiconductor layer on a base substrate by conducting an epitaxial lateral over growth of a nitride semiconductor layer; a second step of forming an asperity pattern on the first nitride semiconductor layer; a third step of forming crystallinity defect-containing portions, due to a state modified from a single crystal state, on at least part of the inner walls of the recessed portions in the asperity pattern on the first nitride semiconductor layer; and a fourth step of forming, by conducting an epitaxial lateral over growth of a nitride semiconductor layer, a second nitride semiconductor layer on the asperity pattern which is formed on the first nitride semiconductor layer and including the crystallinity defect-containing portions.

In this case, in the formation of the crystallinity defect-containing state in the third step, there can be used a surface treatment based on a technique such as reactive ion etching (RIE), plasma etching, ion irradiation or neutral beam irradiation.

By applying these techniques, the portion concerned can be modified from the single crystal state to, for example, an amorphous state, a porous state or a polycrystalline state.

In an embodiment of the present invention, the first step may be a step of forming a continuous layer of the first nitride semiconductor by forming an asperity pattern on a base substrate and by conducting an epitaxial lateral over growth of a nitride semiconductor layer on the asperity pattern.

Additionally, the fourth step may be a step of forming a continuous layer of the second nitride semiconductor by conducting an epitaxial lateral over growth of a nitride semiconductor layer.

The production method of a nitride semiconductor layer-containing composite substrate can also be configured in such a way that after the fourth step has been conducted once, the second step and the fourth step are respectively repeated N times (N≧0), and the third step is repeated M times (M≦N).

The above-described production method of a nitride semiconductor layer-containing composite substrate according to the present embodiment enables to produce the composite substrate at a lower cost than conventional nitride semiconductor substrates and facilitates the enlargement of the caliber of the substrate.

The use of such a substrate as describe above enables to conduct an epitaxial growth of a high-quality nitride semiconductor layer, and enables to realize a higher-quality optical element.

The nitride semiconductor layer-containing structure is also usable as a substrate for use in an epitaxial growth of a nitride semiconductor.

In an embodiment of the present invention, the base substrate may be removed from the composite substrate produced by the above-described production method, and the production method of a nitride semiconductor layer-containing structure can be configured as follows.

The production method of a nitride semiconductor layer-containing structure of the present embodiment includes: a step of producing a composite substrate by using any one of the above-described production methods of a composite substrate according to the embodiments of the present invention; and a step of removing a base substrate from the composite substrate produced by the above-described production method.

In an embodiment of the present invention, the production method of a structure can also be configured in such a way that in the step of removing the base substrate, used as the base substrate is a base substrate in which, on a single crystal substrate, an intermediate film that is homogeneous or heterogeneous to the single crystal substrate is further formed, and the intermediate film is removed by the selective etching.

The production method of a structure can also be configured in such a way that in the step of removing the base substrate, sapphire is used for the base substrate and a laser irradiation is conducted from the base substrate side; and the first nitride semiconductor layer is decomposed in the interface between the sapphire substrate and the nitride semiconductor layer-containing structure.

The production method of a structure can also be configured in such a way that in the step of removing the base substrate, used as the base substrate is a base substrate in which, on a single crystal substrate, an intermediate film that is homogeneous or heterogeneous to the single crystal substrate is further formed, and the intermediate film of the base substrate is selectively removed by a photoelectrochemical etching.

The photoelectrochemical etching as referred to herein means an etching in which a substrate is immersed in an electrolytic solution and etching is conducted while the object to be etched is being irradiated externally with ultraviolet light. According to this method, the positive holes generated in the current constriction layer surface by the ultraviolet irradiation causes a dissolution reaction of the current constriction layer to thereby allow the etching to proceed.

This etching is also referred to as PEC etching (photoelectrochemical etching).

In an embodiment of the present invention, the production method of a structure can also be configured in such a way that in the step of removing the base substrate, the nitride semiconductor layer-containing structure is bonded to a second substrate and then the base substrate is removed.

The above-described production method of a nitride semiconductor layer-containing composite substrate according to the present embodiment more facilitates the removal of the base substrate of the nitride semiconductor, and also enables to reduce the damage, to the nitride semiconductor layer, generated at the time of the removal of the base substrate.

In this way, the production cost can be reduced and the improvement of the production yield can be attained.

Hereinafter, the present embodiments are further described with reference to the accompanying drawings. It is to be noted that in the respective drawings, the same symbols are used for the same members, and hence the descriptions for the redundant portions are omitted.

### First Embodiment

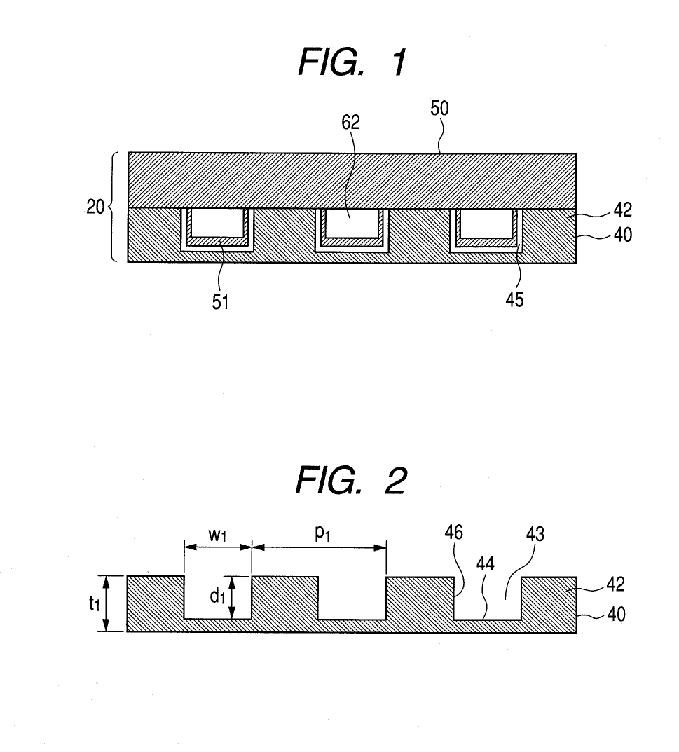

As a first embodiment of the present invention, an example of the nitride semiconductor-containing structure is described. FIG. 1 shows a schematic sectional view for illustrating an example of the nitride semiconductor-containing structure in the present embodiment.

FIG. 1 illustrates a nitride semiconductor-containing structure 20, a first nitride semiconductor layer 40, a raised portion 42 of the first nitride semiconductor layer and a crystallinity defect-containing portion 45 in the first nitride semiconductor layer.

FIG. 1 also illustrates a second nitride semiconductor layer 50, a nitride semiconductor 51 formed in a recessed portion of the first nitride semiconductor layer and a void 62 in the nitride semiconductor structure.

The nitride semiconductor-containing structure 20 of the present embodiment is formed of the first nitride semiconductor layer 40, the second nitride semiconductor layer 50, and the voids 62 in the nitride semiconductor structure formed between these nitride semiconductor layers 40 and 50.

It is a feature that crystallinity defects are found on at least part of the walls surrounding the voids 62 in the nitride semiconductor structure.

The portions that contain crystallinity defects are, for example, the surface of the inner walls of the recessed portions of the first nitride semiconductor layer 40 indicated by the crystallinity defect-containing portions 45 in the first nitride semiconductor layer.

Next, the crystallinity defect-containing portion 45 is described in more detail.

For the convenience of description, FIG. 2 shows only the first nitride semiconductor layer 40 as disassembled from the nitride semiconductor-containing structure 20 in FIG. 1. In FIG. 2, the crystallinity defect-containing portions 45 are also omitted. FIG. 2 illustrates the raised portions 42 of the first nitride semiconductor layer, the recessed portions 43 of the first nitride semiconductor layer and the bottom faces 44 of the recessed portions of the first nitride semiconductor layer.

The crystallinity defect-containing state as referred to herein means a state in which in the crystallinity defect-containing portion 45, the crystal state thereof is a state modified from the single crystal state of the interior (for example, the portion 42) of the first nitride semiconductor layer 40.

For example, the crystallinity defect-containing portion 45 takes an amorphous state, a porous state or a polycrystalline state.

In FIG. 1, the crystallinity defect-containing portion 45 is the whole surface of the inner walls of the recessed portion of the first nitride semiconductor layer 40, but may be merely part of the whole surface such as the bottom face 44 or the side walls 46 shown in FIG. 2.

When the thickness of the crystallinity defect-containing portion 45 ranges from a single atomic layer thickness to a few hundreds nanometers, the effect of the portion 45 is brought about; preferably the thickness concerned ranges from a single atomic layer thickness to a few tens nanometers.

The film thickness of the crystallinity defect-containing portion 45 may be either uniform or nonuniform. In particular, the side walls 46 and the bottom face 44 are not required to be the same in the thickness of the crystallinity defect-containing portion 45.

The role of the crystallinity defect-containing portions 45 is the reduction of the formation rate of the nitride semiconductor on the surface thereof.

As a result of such a role, the size of the voids 62 can be ensured.

Next, the nitride semiconductor 51 formed on the recessed portion of the first nitride semiconductor layer is described. The film thickness of the nitride semiconductor 51 formed on the recessed portion of the first nitride semiconductor layer may be nonuniform depending on the formation condition or the film formation conditions of the crystallinity defect-containing portion 45.

In particular, on the side walls 46 and the bottom face 44, the film thickness of the nitride semiconductor 51 formed on the recessed portion of the first nitride semiconductor layer may be different.

The film thickness of the nitride semiconductor 51 formed on the recessed portion of the first nitride semiconductor layer may be, across the whole surface thereof or partially, as thin as a single atomic layer thickness or less or as thin as negligible. In the position where the crystallinity defect-containing portion 45 is found, the film thickness of the nitride semiconductor 51 formed on the recessed portion of the first nitride semiconductor layer is particularly thin.

In the present embodiment, for the purpose of ensuring the size of the voids 62, the thinner is the film thickness of the nitride semiconductor 51 formed on the recessed portion of the first nitride semiconductor layer, the more preferable.

Next, the voids 62 are described.

The voids 62 are formed between the recessed portions 43 of the first nitride semiconductor layer 40 and the second nitride semiconductor layer 50.

The number of the voids 62 is more than one, and is equal to or less than the number of the recessed portions 43.

As can be seen from FIGS. 1 and 2, when the thickness of the crystallinity defect-containing portion 45 and the thickness of the nitride semiconductor 51 formed on the recessed portion of the first nitride semiconductor layer are both sufficiently thin, the size of the void 62 is roughly determined by the size of the recessed portion 43.

For the purpose of ensuring the film quality of the second nitride semiconductor layer 50, the recessed portions 43 of the first nitride semiconductor layer are preferably distributed in a nearly periodic manner.

Additionally, as for the recessed portions 43 of the first nitride semiconductor layer, preferably the sizes of the respective recessed portions are roughly equal to each other.

The pattern of the recessed portions 43 of the first nitride semiconductor layer as viewed from above the film formation surface is, for example, a set of periodically arranged parallel grooves or a set of periodically arranged independent holes. The inner walls (including the side walls 46 and the bottom faces 44) of the recessed portions 43 of the first nitride semiconductor layer are not required to be flat and smooth.

Additionally, the side walls 46 of the recessed portions 43 of the first nitride semiconductor layer are not required to be vertical. The size of the recessed portions 43 of the first nitride semiconductor layer may be optimized depending on the pattern shape of the recessed portions 43 of the first nitride semiconductor layer, the film thickness t₁ of the first nitride semiconductor layer 40 and the film thickness t₂ of the second nitride semiconductor layer 50.

The size of the recessed portions 43 of the first nitride semiconductor layer is described by taking as an example the case where the pattern is a set of periodically arranged parallel linear grooves.

The length of each of the grooves is set so as for the grooves to cross the area where the growth is intended to occur. For example, when the diameter of the area where the growth is intended to occur is 2 inches φ, the length of each of the grooves is set to be 2 inches at maximum.

As shown in FIG. 2, the period, width and depth of the grooves are represented by p₁, w₁ and d₁, respectively. When t₁>50 nm, it is required to satisfy the following relations: 20 nm<p₁<10t₁, 10 nm<w₁<p₁, 0.2 w₁<d₁<t₁, t₂>w₁. For example, when t₁=8 μm, it is required to satisfy the following relations: 1 μm<p₁<20 μm, 100 nm<w₁<p₁, 20 nm<d₁<8 μm, t₂>200 nm. As a more specific example, it is required to satisfy the following relations: t₁=8 μm, p₁=10 μm, w₁=7 μm, d₁=6 μm, t₂=10 μm.

In this case, the obtained voids 62 have a width of about 7 μm and a depth of 3 μm or more.

The voids 62 can alleviate the strain stress between the first nitride semiconductor layer 40 and the second nitride semiconductor layer 50.

In particular, when the materials of these nitride semiconductor layers 40 and 50 are different from each other, the effect of the voids 62 is remarkable. Consequently, in the nitride semiconductor-containing structure 20, the deformation or the defects due to the strain stress can be reduced in the second nitride semiconductor layer 50, in particular, on the surface of the second nitride semiconductor layer 50.

In the nitride semiconductor-containing structure 20 shown in FIG. 1, the first nitride semiconductor layer 40 and the second nitride semiconductor layer 50 may be either homogeneous to each other or absolutely heterogeneous to each other. Additionally, these nitride semiconductor layers 40 and 50 may be respectively formed of a multilayer film formed of nitride semiconductor films.

The nitride semiconductor as referred to herein means, for example, a gallium nitride compound semiconductor represented by the general formula AlₓGa_{y}In_{1-x-y}N (0≦x≦1, 0≦y≦1, 0≦x+y≦1).

Typical examples thereof include GaN, AlGaN, InGaN, AlN and InN.

Additionally, the nitride semiconductor-containing structure 20 shown in FIG. 1 is formed only of the first nitride semiconductor layer 40 and the second nitride semiconductor layer 50, but may be formed by laminating such a structure a plurality of times. In such a case, in the upper layer portion, the walls that surround the voids may be free from the crystallinity defect-containing portions.

The nitride semiconductor-containing structure 20 is singly usable as a material of optical elements.

The nitride semiconductor-containing structure 20 is also usable as a substrate for the epitaxial growth of a nitride semiconductor film.

Further, the nitride semiconductor-containing structure 20 is also usable in a manner attached to another substrate.

The nitride semiconductor-containing structure 20 of the present embodiment can be produced by the production method to be described in a fourth embodiment.

### Second Embodiment

As a second embodiment of the present invention, an example of the nitride semiconductor-containing composite substrate is described.

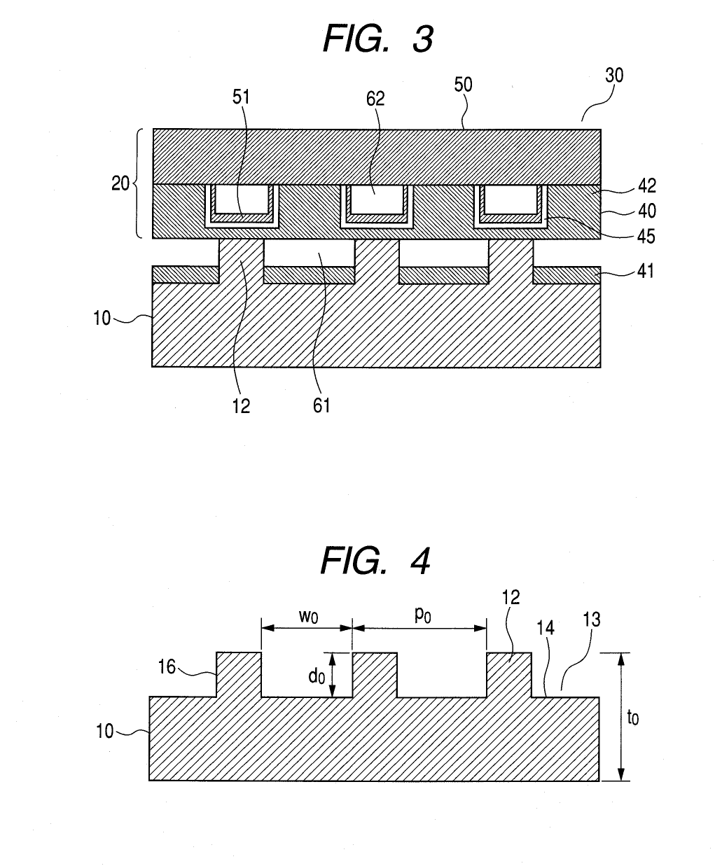

FIG. 3 shows a schematic sectional view for illustrating an example of the nitride semiconductor-containing composite substrate in the present embodiment.

FIG. 3 illustrates a base substrate 10, a raised portion 12 of the base substrate, a nitride semiconductor-containing composite substrate 30, a nitride semiconductor 41 formed in a recessed portion of the base substrate and a void 61 between the base substrate and the nitride semiconductor.

The nitride semiconductor-containing composite substrate 30 in the present embodiment is formed of the base substrate 10 and the nitride semiconductor-containing structure 20.

The base substrate 10 and the structure 20 may be connected to each other without any gap therebetween. When the structure 20 is formed on the base substrate 10 by crystal growth, for the purpose of ensuring the quality of the structure 20, it is preferable to form the voids between the base substrate 10 and the structure 20. As an example, in the composite substrate 30 shown in FIG. 3, the voids 61 are formed between the base substrate 10 and the structure 20.

Next, because the nitride semiconductor-containing structure 20 is the same as in the first embodiment, hereinafter with reference to FIG. 3 and FIG. 4, only the base substrate 10 and the voids 61 are described.

FIG. 4 is a view showing only the base substrate 10 as disassembled from the nitride semiconductor-containing composite substrate 30 shown in FIG. 3.

FIG. 4 illustrates a raised portion 12 of the base substrate, a recessed portion 13 of the base substrate, the bottom face 14 of the recessed portion of the base substrate and the side wall 16 of the recessed portion of the base substrate.

First, the base substrate 10 is described.

The base substrate 10 may be a simple single crystal substrate.

The material of the base substrate 10 is, for example, any of a nitride semiconductor typified by GaN, sapphire, silicon (Si) and silicon carbide (SiC).

In the base substrate 10, according to the intended purpose, on a simple single crystal substrate, an intermediate film homogeneous or heterogeneous to the single crystal substrate may be further formed.

The intermediate film may be a multilayer film. As an example, the intermediate film is a monolayer film or a multilayer film including at least any of GaN, AlGaN, InGaN, AlN and InN.

Further, as shown in FIG. 4, an asperity pattern may be formed on the film formation surface of the base substrate 10.

When the intermediate film is formed, the asperity pattern may be formed so as to reach a midway position of the intermediate film or may be formed so as to penetrate through the intermediate film to reach the interior of the single crystal substrate. Additionally, the intermediate film may be formed after the asperity pattern has been formed.

The inner walls (including the side walls 16 and the bottom faces 14) of the recessed portions 13 of the base substrate are not required to be flat and smooth.

Additionally, the side walls 16 are not required to be vertical, and may be tapered. The inclination angles of the both side walls 16 forming each of the recessed portions are not required to be equal to each other.

Next, the voids 61 are described.

The voids 61 are formed between the recessed portions 13 of the base substrate 10 and the first nitride semiconductor layer 40.

The number of the voids 61 is more than one, and is equal to or less than the number of the recessed portions 13. When the base substrate 10 and the first nitride semiconductor layer 40 are bonded by junction to each other, the size of the voids 61 is roughly determined by the recessed portions 13.

In the case where the nitride semiconductor layer 40 is formed by the lateral growth using the asperity pattern of the base substrate 10, as can be seen from FIGS. 3 and 4, the size of the voids 61 is determined by the size of the recessed portions 13, the thickness of the nitride semiconductor 41 and the thickness of the nitride semiconductor (not shown) formed on the side walls 16 of the recessed portions of the base substrate.

When the base substrate 10 is a substrate formed of a material other than the nitride semiconductor, the film thickness of the nitride semiconductor formed on the side walls 16 of the recessed portions of the base substrate is almost negligible.

The thickness of the nitride semiconductor 41 formed on the recessed portions of the base substrate is determined by the material of the base substrate 10 and the growth conditions of the first nitride semiconductor layer 40, and is frequently half or less the thickness t₁ of the first nitride semiconductor layer 40.

For the purpose of ensuring the film quality of the first nitride semiconductor layer 40, the recessed portions 13 are preferably distributed in a nearly periodic manner.

Additionally, as for the recessed portions 13, preferably the sizes of the respective recessed portions are roughly equal to each other. The pattern of the recessed portions 13 as viewed from above the film formation surface is, for example, a set of periodically arranged parallel grooves or a set of periodically arranged independent holes.

The size of the recessed portions 13 may be optimized depending on the pattern shape of the recessed portions 13, the thickness t₀ of the base substrate 10 and the film thickness t₁ of the first nitride semiconductor layer 40.

The size of the recessed portions 13 is described by taking as an example the case where the pattern is a set of periodically arranged parallel linear grooves.

The length of each of the grooves is set so as for the grooves to cross the area where the growth is intended to occur. For example, when the diameter of the area where the growth is intended to occur is 2 inches φ, the length of each of the grooves is set to be 2 inches at maximum.

As shown in FIG. 4, the period, width and depth of the grooves are represented by p₀, w₀ and d₀, respectively. When t₀>100 μm, it is required to satisfy the following relations: 20 nm<p₀<20 μm, 10 nm<w₀<p₀, 0.2 w₀<d₀<t₀, t₁>w₀. As a more specific example, it is required to satisfy the following relations: t₀=420 μm, p₀=10 μm, w₀=7 μm, d₀=6 μm, t₁=10 μm.

In this case, the obtained voids 61 have a width of about 7 μm and a depth of 3 μm or more.

The presence of the voids 61 enables to alleviate the strain stress between the nitride semiconductor 20 and the base substrate 10. Additionally, the threading dislocation density in the first nitride semiconductor layer 40 can be more reduced when the first nitride semiconductor layer 40 is formed by the lateral growth using the asperity pattern on the base substrate 10 than when the first nitride semiconductor layer 40 is formed on a flat base substrate by direct growth.

The nitride semiconductor-containing composite substrate 30 of the present embodiment can be produced by the production method to be described in a third embodiment.

### Third Embodiment

As a third embodiment of the present invention, an example of the production method of a nitride semiconductor-containing composite substrate is described.

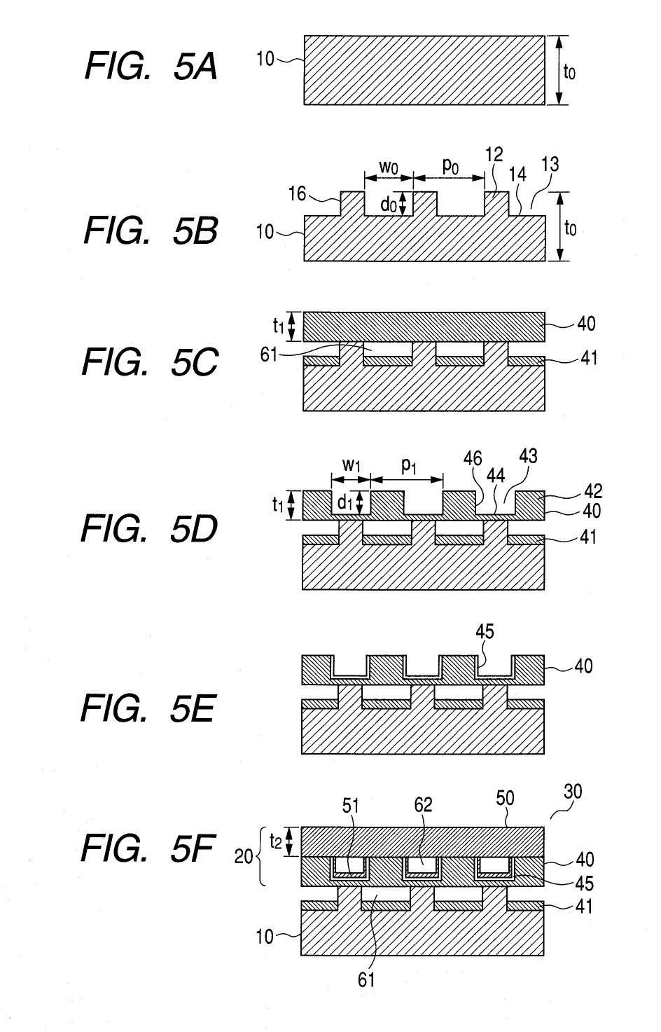

FIGS. 5A to 5F shows the schematic sectional views for illustrating an example of the production method of a nitride semiconductor-containing composite substrate in the present embodiment.

In the production of the composite substrate, first the base substrate 10 is prepared (FIG. 5A).

The base substrate 10 may be a simple single crystal substrate. The material of the base substrate 10 is, for example, any of a nitride semiconductor typified by GaN, sapphire, silicon (Si) and silicon carbide (SiC).

In the base substrate 10, according to the intended purpose, on a simple single crystal substrate, an intermediate film (not shown) homogeneous or heterogeneous to the single crystal substrate may be further formed.

The intermediate film may be a multilayer film. As an example, the intermediate film is a monolayer film or a multilayer film including at least any of GaN, AlGaN, InGaN, AlN and InN.

Next, as shown in FIG. 5B, an asperity pattern is formed on the film formation surface of the base substrate 10. When the intermediate film is formed, the asperity pattern may be formed so as to reach a midway position of the intermediate film or may be formed so as to penetrate through the intermediate film to reach the interior of the single crystal substrate. Additionally, the intermediate film may be formed after the asperity pattern has been formed.

The inner walls (including the side walls 16 and the bottom faces 14) of the recessed portions 13 of the asperity pattern are not required to be flat and smooth.

Additionally, the side walls 16 are not required to be vertical, and may be tapered. The inclination angles of the both side walls 16 forming each of the recessed portions are not required to be equal to each other.

The asperity pattern is formed by the well known lithography technique and etching technique. Examples of the lithography technique include a resist pattern formation technique based on the photolithography technique or the electron beam exposure technique.

According to need, the resist pattern is transferred to a so-called hard mask such as a metal film or a SiO₂ film.

The etching technique is a technique for processing the base substrate 10 by dry or wet etching by using as the mask (not shown) the resist pattern or the hard mask pattern.

The recessed portions 13 of the base substrate 10 thus formed are preferably distributed in a nearly periodic manner.

Additionally, as for the recessed portions 13, preferably the sizes of the respective recessed portions are roughly equal to each other. The pattern of the recessed portions 13 as viewed from above the film formation surface is, for example, a set of periodically arranged parallel grooves or a set of periodically arranged independent holes.

The size of the recessed portions 13 may be optimized depending on the pattern shape of the recessed portions 13, the thickness t₀ of the base substrate 10 and the film thickness t₁ of the first nitride semiconductor layer 40.

The size of the recessed portions 13 is described by taking as an example the case where the pattern is a set of periodically arranged parallel linear grooves.

The length of each of the grooves is set so as for the grooves to cross the area where the growth is intended to occur. For example, when the diameter of the area where the growth is intended to occur is 2 inches φ, the length of each of the grooves is set to be 2 inches at maximum.

As shown in FIG. 5B, the period, width and depth of the grooves are represented by p₀, w₀ and d₀, respectively. When t₀>100 μm, it is required to satisfy the following relations: 20 nm<p₀<20 μm, 10 nm<w₀<p₀, 0.2 w₀<d₀<t₀, t₁>w₀. As a more specific example, it is required to satisfy the following relations: t₀=420 μm, p₀=10 μm, w₀=7 μm, d₀=6 μm, t₁=10 μm.

According to need, the arrangement direction of the asperity pattern is matched to the crystallographic orientation of the base substrate 10.

Next, the first step shown in FIG. 5C of forming the continuous layer of the first nitride semiconductor layer 40 is conducted.

In this case, the voids 61 are formed between the base substrate 10 and the first nitride semiconductor layer 40. The material of the first nitride semiconductor layer 40 is, for example, a gallium nitride compound semiconductor represented by the general formula AlₓGa_{y}In_{1-x-y}N (0≦x≦1, 0≦y≦1, 0≦x+y≦1).

Typical examples thereof include GaN, AlGaN, InGaN, AlN and InN. The first nitride semiconductor layer 40 may be bonded to the base substrate 10 by substrate junction.

The substrate junction as referred to herein means, for example, a junction including a surface activation step and a heating-pressurizing step. The heating temperature ranges from room temperature to 1000° C.

The first nitride semiconductor layer 40 may be formed on the base substrate 10 by crystal growth. Examples of the crystal growth method include the metal organic chemical vapor deposition method (MOCVD method), the hydride vapor phase epitaxy method (HYPE method) and the molecular beam epitaxy method (MBE method). For the purpose of reducing the threading dislocation density in the first nitride semiconductor layer 40 and forming the voids 61, preferable is the crystal growth conditions such that the lateral growth of the first nitride semiconductor layer 40 is preferentially conducted.

For the purpose of conducting preferentially the lateral growth, the arrangement direction of the asperity pattern of the base substrate 10 is beforehand matched to the intended crystallographic orientation.

In the case of the crystal growth, the film of the first nitride semiconductor, represented by the nitride semiconductor 41 formed on the recessed portions of the base substrate, is also formed on the bottom face 14 of the recessed portions 13 of the base substrate 10.

The crystal growth conditions are, for example, the following heretofore known MOCVD growth conditions. In other words, in an MOCVD apparatus, first a few tens nanometers of nitride semiconductor buffer layer is grown at a substrate temperature of 300 to 700° C.

In the case of GaN, for example, trimethylgallium (TMG) is used as a Group III material and ammonia (NH₃) is used as a Group V material.

Next, the substrate temperature is increased to about 1000° C., the lateral growth of the nitride semiconductor is conducted.

For example, a 10-μm-thick GaN film is formed. In this case, TMG and NH₃ are used as the materials. When an impurity is intended to be introduced, an appropriate gas is introduced into the film formation apparatus. For example, as a donor gas for GaN, silane (SiH₄) is appropriate.

By the lateral growth, there is obtained a continuous layer of the first nitride semiconductor layer 40 which is wholly flat and in which the threading dislocation density in the vicinity of the surface thereof is reduced in the upper region of the recessed portions 13 of the base substrate.

In the region of the first nitride semiconductor layer 40 in which region the threading dislocation density is reduced, the threading dislocation density becomes 1×10⁸ cm⁻² or less.

This value is lower by an order of magnitude or more than the threading dislocation density of the nitride semiconductor film formed on the raised portions 12 of the base substrate.

Under the above-described crystal growth conditions, when p₀=10 μm, w₀=7 μm, d₀=6 μm and t₁=10 μm, the obtained voids 61 have a width of about 7 μm and a depth of about 3 μm or more.

Next, as shown in FIG. 5D, the second step of forming an asperity pattern on the continuous layer of the first nitride semiconductor layer 40 is conducted.

The asperity pattern on the continuous layer is formed by the heretofore known lithography technique and etching technique. Examples of the lithography technique include a resist pattern formation technique based on the photolithography technique or the electron beam exposure technique.

According to need, the resist pattern is transferred to a so-called hard mask such as a metal film or a SiO₂ film.

The use of the hard mask is particularly required in the case where a deep asperity pattern is formed.

The etching technique is a technique for processing the first nitride semiconductor layer 40 by dry or wet etching by using as the etching mask (not shown) the resist pattern or the hard mask pattern. The dry etching is, for example, the dry etching using the plasma of a reactive gas.

The reactive gas is a single gas or a mixed gas including two or more gases, and may be optimized according to the composition of the first nitride semiconductor layer 40.

For example, in the case where the first nitride semiconductor layer 40 is a GaN layer, as main reactive gases, chlorine-containing gases (for example, Cl₂, BCl₃, SiCl₄) or CH₄-containing gases are used.

When the recessed portions 43 of the asperity pattern are formed, it is preferable to remove as much as possible the portion relatively high in the threading defect density in the first nitride semiconductor layer 40.

This way enables to obtain a film more reduced in the defect density, in the subsequent film formation of the nitride semiconductor.

The portion high in the threading defect density is located, for example, on the raised portions 12 of the base substrate 10. When the etching mask for the first nitride semiconductor layer 40 is formed, the appropriate conduction of the design of the mask shape and the positioning at the time of the photolithography enables the above-described formation of the recessed portions 43 of the asperity pattern.

The size of the recessed portions 43 of the asperity pattern may be optimized depending on the pattern shape of the recessed portions 43, the film thickness t₁ of the first nitride semiconductor layer 40 and the film thickness t₂ of the second nitride semiconductor layer 50 to be formed later.

The size of the recessed portions 43 of the asperity pattern is described by taking as an example the case where the pattern is a set of periodically arranged parallel linear grooves.

The length of each of the grooves is set so as for the grooves to cross the area where the growth is intended to occur. For example, when diameter of the area where the growth is intended to occur is 2 inches φ, the length of each of the grooves is set to be 2 inches at maximum.

As shown in FIG. 5D, the period, width and depth of the grooves are represented by p₁, w₁ and d₁, respectively. When t₁>50 nm, it is required to satisfy the following relations: 20 nm<p₁<10t₁, 10 nm<w₁<p₁, 0.2 w₁<d₁<t₁, t₂>w₁.

For example, when t₁=10 μm, it is required to satisfy the following relations: 1 μm<p₁<20 μm, 100 nm<w₁<p₁, 100 nm<d<8 μm, t₂>200 nm. As a more specific example, it is required to satisfy the following relations: t₁=10 μm, p₁=10 μm, w₁=7 μm, d₁=6 μm, t₂=10 μm.

Next, as shown in FIG. 5E, the third step of forming the crystallinity defect-containing state in the continuous layer of the first nitride semiconductor layer 40 is conducted.

The portions 45 having the crystallinity defect-containing state are formed on at least part of the inner walls of the recessed portions 43 of the asperity pattern.

In FIG. 5E, the portions 45 having the crystallinity defect-containing state are formed on the whole surface of the inner walls of the recessed portions 43 of the asperity pattern, but may be formed only on part of the recessed portions 43 of the asperity pattern, such as only on the bottom faces 44 or only on the side walls 46 shown in FIG. 5D.

The thickness of the portions 45 having the crystallinity defect-containing state may be either uniform or nonuniform.

In particular, the side walls 46 and the bottom faces 44 are not required to be the same with respect to the thickness of the portions 45 having the crystallinity defect-containing state.

The role of the portions 45 having the crystallinity defect-containing state is the reduction of the formation rate of the nitride semiconductor on the surface thereof.

As a method for forming the portion 45 having the crystallinity defect-containing state, a surface treatment based on a technique such as reactive ion etching (RIE), plasma etching, ion irradiation or neutral beam irradiation is applied to modify the portion concerned from the single crystal state.

The state of the portion concerned after modification is, for example, an amorphous state, a porous state or a polycrystalline state.

At the time of the surface treatment, the portion that is not intended to be modified is protected with a mask (not shown).

The above-described protective mask may be newly formed by using the formation method of the etching mask described in the second step, or the etching mask may be used as the protective mask simply as it is. The thickness of the portion 45 is controllable by the above-described surface treatment conditions and the surface treatment time, and ranges from a single atomic layer thickness to a few hundreds nanometers.

Next, the fourth step, shown in FIG. 5F, of forming the continuous layer of the second nitride semiconductor layer 50 is conducted.

In this case, the voids 62 are formed between the second nitride semiconductor layer 50 and the first nitride semiconductor layer 40.

The material of the second nitride semiconductor layer is, for example, a gallium nitride compound semiconductor represented by the general formula AlₓGa_{y}In_{1-x-y}N (0≦x≦1, 0≦y≦1, 0≦x+y≦1).

Typical examples thereof include GaN, AlGaN, InGaN, AlN and InN. The second nitride semiconductor layer 50 and the first nitride semiconductor layer 40 may be either homogeneous to each other or absolutely heterogeneous to each other. Additionally, the second nitride semiconductor layer 50 may be formed of a multilayer film.

The formation method of the second nitride semiconductor layer 50 is similar to the crystal growth method of the first nitride semiconductor layer 40 described in the first step, and is a lateral growth mainly using the well known MOCVD.

At the same time as the lateral growth of the second nitride semiconductor layer 50, the nitride semiconductor 51 may be formed also in the interior of the recessed portions 43 of the first nitride semiconductor layer.

The film thickness of the nitride semiconductor 51 may be nonuniform depending on the formation conditions or the film formation conditions of the crystallinity defect-containing portions 45.

In particular, on the side walls 46 and the bottom faces 44 shown in FIG. 5D, the film thickness of the nitride semiconductor 51 may be nonuniform.

The presence of the crystallinity defect-containing portions 45 reduces, on the inner walls 43, in particular, on the side walls 46, the formation rate of the nitride semiconductor to make the film thickness of the nitride semiconductor 51 negligibly thin, as the case may be. Consequently, the size of the voids 62 can be ensured. The thus obtained voids 62, as an example, have a width of about 7 μm and a depth of 3 μm or more when the film thickness t₂ of the second nitride semiconductor layer 50 is set as t₂=10 μm. The threading dislocation density of the film of the second nitride semiconductor layer 50 formed by such a lateral growth is 3×10⁷ cm⁻² or less. This value is lower than the threading dislocation density of the nitride semiconductor film based on the direct crystal growth on the first nitride semiconductor layer 40 without formation of the asperity pattern.

In the process of the crystal growth of the second nitride semiconductor layer 50, part of the crystallinity defect-containing portions 45 become polycrystalline due to recrystallization, but does not become a single crystal that is integrated with the raised portions 42.

The voids 62 can alleviate the strain stress between the first nitride semiconductor layer 40 and the second nitride semiconductor layer 50. In particular, when the material of the first nitride semiconductor layer 40 and the material of the second nitride semiconductor layer 50 are different from each other, such an alleviation effect is remarkable.

Accordingly, the presence of the voids 62 drastically reduces the effect exerted by the base substrate 10 on the second nitride semiconductor layer 50 as compared to the effect exerted by the base substrate 10 on the first nitride semiconductor layer 40.

Consequently, in the second nitride semiconductor layer 50, the deformation and the defects due to the strain stress can be reduced.

According to the present embodiment, the production of the nitride semiconductor-containing composite substrate in the present invention is enabled.

### Fourth Embodiment

As a fourth embodiment of the present invention, an example of the production method of a nitride semiconductor-containing structure is described.

The production method of a nitride semiconductor-containing structure 20 in the present embodiment is characterized by including: a step of producing a nitride semiconductor-containing composite substrate 30; and a step of removing the base substrate 10 of the composite substrate 30.

The production method of the composite substrate 30 has been described in the third embodiment, and hence is omitted herein. Hereinafter, the step of removing the base substrate 10 and others are described.

The base substrate 10 can be removed with selective etching by taking advantage of the difference in etching resistance between the materials.

For example, when the material of the base substrate 10 is Si, the base substrate 10 can be removed by dissolving only Si with KOH.

When the base substrate 10 is formed of a relatively easily polishable material, the base substrate 10 may be removed by polishing.

When the base substrate 10 includes an intermediate film removable with selective etching, the base substrate 10 can be removed by removing the intermediate film by selective etching.

When the base substrate 10 is a transparent substrate made of a material such as GaN or sapphire, the base substrate 10 can also be removed by the heretofore known laser lift-off (also referred to as LLO) method.

Additionally, when the base substrate 10 is a transparent substrate, the base substrate 10 can also be removed by selectively removing the intermediate film of the base substrate by the heretofore known photoelectrochemical etching. For example, when the base substrate 10 is made of GaN or sapphire, InGaN is used for the intermediate film.

Used as a light source is a lamp or a laser that emits light not to be substantially absorbed by the base substrate 10, such as a Xe—Hg lamp. As an etching solution, for example, an aqueous solution of KOH is used.

Additionally, the base substrate 10 may be removed after the composite substrate 30 has been attached to an appropriate second substrate. Examples of the attaching method include a junction method using wax or resin and a direct junction method including a surface activation step and a heating-pressurizing step.

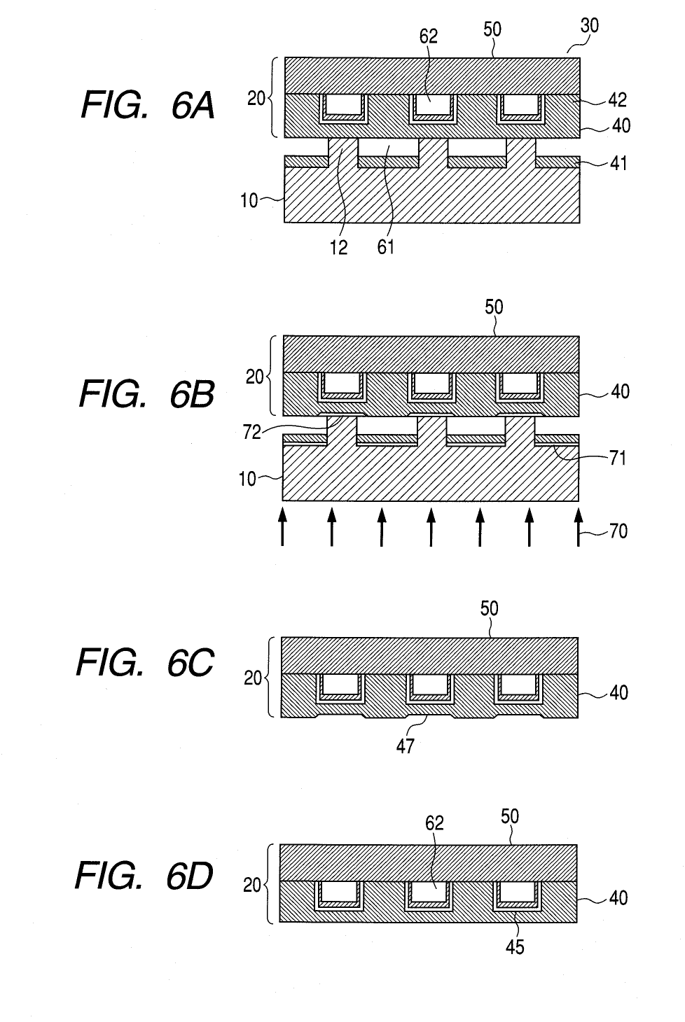

Hereinafter, with reference to FIGS. 6A to 6D, the removal of the base substrate 10 by the LLO method is described in detail.

The description is made by taking as an example the nitride semiconductor-containing composite substrate 30 described in the second embodiment.

FIG. 6A shows the nitride semiconductor-containing composite substrate 30 before a treatment is conducted.

FIG. 6B shows an electromagnetic wave irradiation step. The electromagnetic wave is not substantially absorbed by the base substrate 10, but is absorbed by the first nitride semiconductor layer of the first nitride semiconductor layer 40, and is for example a laser light.

For example, when the base substrate 10 is made of sapphire and the first nitride semiconductor layer 40 is made of GaN, a laser light having an oscillation wavelength of 370 nm or shorter is preferable. Examples of the usable laser include the following excimer lasers: ArF (193 nm), KrF (248.5 nm) and XeCl (308 nm).

The electromagnetic wave irradiation time is only required to be such that allows the first nitride semiconductor layer 40 to be decomposed and the base substrate 10 to be thereby removed, and the irradiation is conducted by appropriately regulating the irradiation time depending on the type of the electromagnetic wave.

As the irradiation method, as shown in FIG. 6B, the whole area may be irradiated with a laser light along the direction 70 from the back side of the base substrate 10.

Alternatively, the xy stage with the substrate placed thereon is moved, and finally the laser irradiation may be made to the whole area from the back side of the base substrate 10.

By the electromagnetic wave irradiation, as shown in FIG. 6B, the portions 71 and 72 in which the nitride semiconductor has been decomposed are formed respectively on the interface with the bottom faces of the recessed portions of the base substrate 10 and the interface with the top faces of the raised portions of the base substrate 10.

For example, when the first nitride semiconductor layer 40 is made of GaN, GaN is decomposed into Ga and N₂, and hence the portions 71 and 72 in which the nitride semiconductor has been decomposed are mainly formed of Ga.

The N₂ gas diffuses explosively into the voids 61. If the voids 61 are absent, the explosive diffusion of the N₂ gas generates a large number of microcracks in the first nitride semiconductor layer 40.

The presence of the voids 61 offers the escape routes of the N₂ gas, and thus enables to drastically reduce the generation of the microcracks.

Thus, the damage exerted by the removal of the substrate on the nitride semiconductor-containing structure 20 can be reduced.

As a result of the electromagnetic wave irradiation, the connection in the contact interface between the nitride semiconductor-containing structure 20 and the base substrate 10 is mainly effected by Ga.

Even an application of slight force enables to remove the base substrate 10, to yield the structure as shown in FIG. 6C. The nitride semiconductor-containing structure 20 as produced can be used. According to need, the following additional processings 1 to 3 are conducted.

In the additional processing 1, the Ga and the like attached to the surface of the nitride semiconductor-containing structure 20 are removed. For that purpose, washing with diluted hydrochloric acid is conducted.

In the additional processing 2, as shown in FIG. 6C, the depressed portions 47 are formed on the side of the first nitride semiconductor layer 40 in the interface in contact with the first nitride semiconductor layer 40 and the base substrate 10. At this time, the damage due to the electromagnetic wave irradiation still remains in the depressed portions 47 in the first nitride semiconductor layer.

According to the analysis based on the cross-section transmission electron microscope (TEM) method or the Rutherford back scattering (RBS) method, it can be seen that the damage is confined within the depth of 500 nm from the interface depending on the electromagnetic wave irradiation conditions.

The removal of this damage layer almost eliminates the damage to the nitride semiconductor-containing structure 20 due to the substrate removal.

Examples of the method for removing the depressed portions 47 in the first nitride semiconductor layer include mechanical polishing, chemical mechanical polishing (CMP), ion milling and gas cluster ion beam (GCIB) etching.

In the additional processing 3, as shown in FIG. 6D, when the surface of the first nitride semiconductor layer 40 is intended to be planarized or the film thickness of the first nitride semiconductor layer 40 is intended to be regulated, the surface of the first nitride semiconductor layer 40 is made flat by the same method as applied to the removal of the depressed portions 47 of the first nitride semiconductor layer.

Consequently, there can be obtained the nitride semiconductor-containing structure 20 with the flat bottom face.

According to the present embodiment, the production of the nitride semiconductor-containing structure in the present invention is enabled.

### Examples

Hereinafter, Examples of the present invention are described.

### Example 1

In Example 1, a specific example of the nitride semiconductor-containing structure that has been described in the first embodiment is described with reference to FIGS. 1 and 2.

The description of the portions that overlap the portions described in the first embodiment is omitted.

In present Example, the first nitride semiconductor layer 40 and the second nitride semiconductor layer 50 are both a single crystal of GaN.

The thickness t₁ of the first nitride semiconductor layer 40 is set as t₁=8 μm and the thickness t₂ of the second nitride semiconductor layer 50 is set as t₂=10 μm. The GaN-containing structure 20 is formed of these nitride semiconductor layers 40 and 50 and the voids 62 formed between these nitride semiconductor layers 40 and 50, and is characterized in that at least part of the walls surrounding the voids 62 contain crystallinity defects.

In the crystallinity defect-containing portions 45, the crystalline state thereof is modified from a single crystal state of the interior (for example, the portion 42) of the first nitride semiconductor layer 40.

The crystalline state of the crystallinity defect-containing portions 45 includes at least a polycrystalline state.

The area of the crystallinity defect-containing portions 45 covers almost the whole surface of the inner walls of the recessed portions 43 of the first nitride semiconductor layer 40.

The thickness of the crystallinity defect-containing portions 45 ranges from a single atomic layer thickness to a few tens nanometers, and is nonuniform in terms of the atomic layer level.

The role of the crystallinity defect-containing portions 45 is the reduction of the formation rate of the GaN on the surface thereof. As a result of such a role, the size of the voids 62 can be ensured.

The film thickness of the nitride semiconductor 51 formed on the inner walls of the recessed portions 43 of the first nitride semiconductor layer may be nonuniform depending on the film formation conditions or the formation condition of the crystallinity defect-containing portions 45.

For example, the film thickness of the nitride semiconductor 51 is as negligibly thin as a few atomic layer thickness on the side walls 46 and is 2 μm or less on the bottom faces 44.

The voids 62 are formed between the recessed portions 43 of the first nitride semiconductor layer and the second nitride semiconductor layer 50.

The number of the voids 62 is more than one, and is equal to the number of the recessed portions 43 of the first nitride semiconductor layer.

As can be seen from FIGS. 1 and 2, the size of the voids 62 is roughly determined by the size of the recessed portions 43 and the thickness of the nitride semiconductor 51.

For the purpose of ensuring the film quality of the second nitride semiconductor layer 50, the recessed portions 43 of the first nitride semiconductor layer are distributed in a nearly periodic manner. Additionally, the sizes of the respective recessed portions 43 of the first nitride semiconductor layer are roughly equal to each other.

The pattern of the recessed portions 43 of the first nitride semiconductor layer as viewed from above the film formation surface is a set of nearly periodically arranged parallel grooves.

The inner walls (including the side walls 46 and the bottom faces 44) of the recessed portions 43 of the first nitride semiconductor layer are not flat and smooth in terms of the atomic level.

The inclination angles of the side walls 46 of the recessed portions 43 of the first nitride semiconductor layer are about 85°.

The size of the recessed portions 43 of the first nitride semiconductor layer is as follows.

The length of each of the grooves is such that the grooves cross a 2-inch φ substrate and the length of each of the grooves is 2 inches at maximum.

As shown in FIG. 2, when the groove period p₁=10 μm, the groove width w₁=7 μm and the grove depth d₁=6 μm, the obtained voids 62 have a width of about 7 μm and a depth of 4 μm or more.

The voids 62 enable to alleviate the strain stress between the first nitride semiconductor layer 40 and the second nitride semiconductor layer 50. Consequently, in the nitride semiconductor-containing structure 20, the deformation or the defects due to the strain stress can be reduced.

The GaN-containing structure 20 of present Example can be produced by the production method to be described in Example 4.

### Example 2

In Example 2, a specific example of the nitride semiconductor-containing composite substrate that has been described in the second embodiment is described with reference to FIGS. 3 and 4.

The description of the portions that overlap the portions described in the second embodiment is omitted.

In present Example, the nitride semiconductor-containing composite substrate 30 is formed of a base substrate 10 made of sapphire and the nitride semiconductor-containing structure 20 described in Example 1.

The voids 61 are formed between the base substrate 10 and the structure 20, and the voids 62 are formed between the first nitride semiconductor layer 40 and the second nitride semiconductor layer 50.

Because the nitride semiconductor-containing structure 20 is the same as in Example 1, hereinafter with reference to FIG. 3 and FIG. 4, only the base substrate 10 and the voids 61 are described.

First, the base substrate 10 is described.

The base substrate 10 is a 2-inch φ sapphire single crystal substrate and the thickness t₀ thereof is set as t₀=420 μm.

As shown in FIG. 4, the film formation surface of the base substrate 10 is the C-plane, and periodic linear grooves are formed in a manner nearly parallel to the “11-20” direction of the base substrate 10.

The length of each of the grooves is set so as for the grooves to cross the whole area of the base substrate 10, and the length of each of the grooves is 2 inches at maximum.

It is set that the groove period p₀=10 μm, the groove width w₀=7 μm and the groove depth d₀=6 μm.

Next, the voids 61 are described.

The voids 61 are formed between the recessed portions 13 of the base substrate 10 and the first nitride semiconductor layer 40.

The number of the voids 61 is equal to the number of the recessed portions 13. The size of the voids 61 is roughly determined by the recessed portions 13 and the nitride semiconductor 41 formed on the bottom faces 14 of the recessed portions 13.

The film thickness of the nitride semiconductor formed on the side wall 16 portions of the recessed portions 13 is nearly negligible.

The thickness of the nitride semiconductor 41 is 3 μm or less. Specifically, the voids 61 cross the base substrate 10 and have a length of 2 inches at maximum, a width of about 7 μm and a depth of about 3 μm or more.

The presence of the voids 61 enables to alleviate the strain stress between the nitride semiconductor 20 and the sapphire base substrate 10 which are heterogeneous to each other.

Additionally, the threading dislocation density in the first nitride semiconductor layer 40 can be more reduced when the first nitride semiconductor layer 40 is formed by the lateral growth using the asperity pattern on the base substrate 10 than when the first nitride semiconductor layer 40 is formed on a flat base substrate by direct growth.

The nitride semiconductor-containing composite substrate 30 of the present example can be produced by the production method to be described in Example 3.

### Example 3

In Example 3, a specific example of the production of the nitride semiconductor-containing composite substrate that has been described in the third embodiment is described with reference to FIGS. 5A to 5F.

The description of the portions that overlap the portions described in the third embodiment is omitted.

First a base substrate 10 is prepared.

FIG. 5A shows a sapphire base substrate 10. The size of the base substrate 10 is 2 inches φ and the thickness t₀ thereof is set as t₀=420 μm. The film formation surface of the base substrate 10 is the C-plane.

Further, as shown in FIG. 5B, on the film formation surface of the base substrate 10, periodic linear grooves are formed in a manner nearly parallel to the “11-20” direction of the base substrate 10.

As the formation method, the well known lithography technique and etching technique are used (not shown).

First, on the film formation surface of the base substrate 10, an about 300-nm Cr film is deposited by sputtering.

Then, by the photolithography technique, an intended resist pattern is formed on the Cr film.

In this case, the positioning of the mask and the substrate is conducted in such a way that the linear grooves are arranged so as to be nearly parallel to the “11-20” direction of the base substrate 10.

Then, the resist pattern is used as the etching mask, and the pattern is transferred to the Cr film by applying the RIE with a mixed gas including chlorine (Cl₂), O₂ and Ar, and thus a hard mask made of Cr is formed.

Then, by applying oxygen plasma, the resist is detached. By using the Cr hard mask, and by applying the RIE with a chlorine-containing gas, the sapphire substrate is etched to the intended depth.

Finally, the Cr hard mask is completely removed with a commercially offered Cr etchant. In the obtained linear groove pattern, the length of each of the grooves is set so as for the grooves to cross the whole area of the base substrate 10, and is set to be 2 inches at maximum, and it is set that the period p₀=10 μm, the width w₀=7 μm and the depth d₀=6 μm.

The inclination angles of the side walls 16 are about 85°.

Next, the first step, shown in FIG. 5C, of forming the continuous layer of the first nitride semiconductor layer 40 is conducted.

In this case, the voids 61 are formed between the base substrate 10 and the first nitride semiconductor layer 40. The material of the first nitride semiconductor layer 40 is GaN.

The first nitride semiconductor layer 40 is formed on the base substrate 10 by the crystal growth based on MOCVD.

For the purpose of reducing the threading dislocation density in the first nitride semiconductor layer 40 and forming the voids 61, the first nitride semiconductor layer 40 is formed under the crystal growth conditions that the lateral growth is preferentially conducted.

By the crystal growth, at the same time as the formation of the first nitride semiconductor layer 40, the GaN film represented by the nitride semiconductor 41 is formed also on the bottom faces 14 of the recessed portions 13 of the base substrate 10.

The crystal growth conditions are, for example, the following heretofore known MOCVD growth conditions. Specifically, in the MOCVD apparatus, first a few tens-nm GaN buffer layer is grown at a substrate temperature of 500° C. Then, the substrate temperature is increased to about 1000° C., and the lateral growth of GaN is conducted to form an about 10-μm thick GaN continuous layer of the first nitride semiconductor layer 40.

When the GaN continuous layer is formed, trimethylgallium (TMG) is used as a Group III material and ammonia (NH₃) is used as a Group V material.

Under the crystal growth conditions, the thickness of the nitride semiconductor 41 is 3 μm or less and GaN is scarcely formed on the side walls 16 of the recessed portions of the base substrate.

Specifically, the voids 61 cross the base substrate 10 and have a length of 2 inches at maximum, a width of about 7 μm and a depth of about 3 μm or more.

The threading dislocation density in the first nitride semiconductor layer 40 formed by such a lateral growth is lower than the threading dislocation density of the GaN film formed by the crystal growth on the substrate without formation of the asperity pattern.

In particular, in a portion of the first nitride semiconductor layer 40 mainly formed by the lateral growth (for example, the portion located directly above the recessed portions 13 of the base substrate), the threading dislocation density is 1×10⁸ cm⁻² or less.

The evaluation of the threading dislocation density is conducted with an atomic force microscope (AFM) or the like.

Next, the second step, shown in FIG. 5D, of forming the asperity pattern on the GaN continuous layer of the first nitride semiconductor layer 40 is conducted.

The asperity pattern is formed of periodic linear grooves nearly parallel to the pattern on the sapphire substrate 10 shown in FIG. 5B, and the period of the asperity pattern is the same as that of the pattern on the sapphire substrate 10.

Specifically, p₁=p₀=10 μm. However, when the recessed portions 43 of the asperity pattern are formed, the relatively high threading dislocation density portion of the first nitride semiconductor layer 40 is removed as much as possible. This way enables to obtain a film more reduced in the defect density, in the subsequent film formation of the nitride semiconductor. In other words, the bottom faces 44 of the recessed portions 43 are formed directly on the raised portions 12 of the base substrate 10.

This can be easily realized if the design of the mask shape and the positioning at the time of photolithography are appropriately conducted when the etching mask of the first nitride semiconductor layer 40 is formed.

As the method of forming an asperity pattern on the first nitride semiconductor layer 40, the well known lithography technique and etching technique are used (not shown).

For example, first, by using the lift-off method, an about 500-nm thick Ni pattern is formed on the top surface of the first nitride semiconductor layer 40.

Then, by using the Ni pattern as the hard mask, and by applying the RIE with a mixed gas including Cl₂ and BCl₃ or the like, the first nitride semiconductor layer 40 is etched to the intended depth. Finally, the Ni hard mask is completely removed with a 3.5% aqueous solution of FeCl₃ as an etchant by heating at about 50° C.

The length of each of the grooves of the obtained linear grove pattern is set so as for the grooves to cross the whole area of the base substrate 10, and the length of each of the grooves is 2 inches at maximum. It is set that the period p₁=10 μm, the groove width w₁=7 μm and the groove depth d₁=6 μm. The inclination angles of the side walls 16 are about 85°.

Next, the third step, shown in FIG. 5E, of forming the crystallinity defect-containing state in the first nitride semiconductor layer 40 is conducted.

As the method for forming the portion 45 having the crystallinity defect-containing state, the whole surface of the inner walls of the recessed portions 43 of the first nitride semiconductor layer is converted into an amorphous state by, for example, Ar ion irradiation.

The thickness of the crystallinity defect-containing portions 45 can be controlled by the Ar ion acceleration energy and Ar ion irradiation time, ranges from a single atomic layer thickness to a few hundreds nanometers, and is not required to be uniform.

Next, the fourth step, shown in FIG. 5F, of forming the continuous layer of the second nitride semiconductor layer 50 is conducted. In this case, the voids 62 are formed between the second nitride semiconductor layer 50 and the first nitride semiconductor layer 40.

The material of the second nitride semiconductor layer 50 is, for example, single crystal GaN.

The method of forming the second nitride semiconductor layer 50 is similar to the crystal growth method of the first nitride semiconductor layer 40 described in the first step, and is the lateral growth mainly using the well known MOCVD.

In this case, however, the formation of the low temperature buffer layer becomes unnecessary.

At the same time as the lateral growth of the second nitride semiconductor layer 50, the nitride semiconductor 51 may be formed in the interior of the recessed portions 43 of the first nitride semiconductor layer 40.

The film thickness of the nitride semiconductor 51 may be nonuniform depending on the formation conditions or the film formation conditions of the crystallinity defect-containing portions 45.

The presence of the crystallinity defect-containing portions 45 reduces the formation rate of GaN on the inner walls, in particular the side walls 46 of the recessed portions 43 of the first nitride semiconductor layer.

Consequently, the size of the voids 62 can be ensured.

When the film thickness t₂ of the second nitride semiconductor layer 50 is set as t₂=10 μm, the obtained voids 62 has a width of about 6 μm and a depth of 3 μm or more.

The threading dislocation density of the film of the second nitride semiconductor layer 50 formed by such lateral growth is 1×10⁷ cm⁻² or less.

This value is lower than the threading dislocation density of the GaN film based on the direct crystal growth on the first nitride semiconductor layer 40 without formation of the asperity pattern.

The voids 62 enable to alleviate the strain stress between the first nitride semiconductor layer 40 and the second nitride semiconductor layer 50.

Accordingly, the effect exerted by the base substrate 10 on the second nitride semiconductor layer 50 is significantly reduced as compared to the effect exerted by the base substrate 10 on the first nitride semiconductor layer 40.

Consequently, in the second nitride semiconductor layer 50, the deformation and the defects due to the strain stress can be reduced.

According to present Example, the production of the nitride semiconductor-containing composite substrate in the present invention is enabled.

### Example 4

In Example 4, a specific example of the production of the nitride semiconductor-containing structure 20 that has been described in the fourth embodiment is described with reference to FIGS. 6A to 6D.

The description of the portions that overlap the portions described in the fourth embodiment is omitted.

The production method of the nitride semiconductor-containing structure 20 is characterized by including a step of producing the nitride semiconductor-containing composite substrate 30 and a step of removing the base substrate 10 of the composite substrate 30.

The production method of the composite substrate 30 has been described in Example 3, and hence the description thereof is omitted herein. Hereinafter, the step of removing the sapphire base substrate 10 and other steps are described.

The removal of the base substrate 10 is conducted by the heretofore known LLO method.

FIG. 6A shows the GaN-containing composite substrate 30 before being subjected to the LLO treatment.

FIG. 6B illustrates the electromagnetic wave irradiation step.

The electromagnetic wave is, for example, a KrF excimer laser light, and the wavelength thereof is 248.5 nm, the energy density thereof is about 600 mJ/cm² and the laser pulse width thereof is about 20 ns. The laser irradiation is conducted from the sapphire substrate side 70.

The composite substrate 30 is placed on the xy stage, and the stage is moved in such a way that the irradiation is conducted so as to evenly irradiate the base substrate 10 from the circumferential portion to the inner portion of the base substrate 10. The movement speed is optimized according to the exfoliation condition of the base substrate 10.

As shown in FIG. 6B, the electromagnetic wave irradiation forms the portions 71 and 72, in which the nitride semiconductor GaN is decomposed, respectively on the interface with the bottom faces of the recessed portions of the base substrate 10 and on the interface with the top faces of the raised portions of the base substrate 10.

In this case, GaN is decomposed into Ga and N₂, and hence the decomposition-undergoing portions 71 and 72 are mainly formed of Ga.

The N₂ gas diffuses explosively into the voids 61. If the voids 61 are absent, the explosive diffusion of the N₂ gas generates a large number of microcracks in the first nitride semiconductor layer 40.

The presence of the voids 61 offers the escape routes of the N₂ gas, and thus enables to drastically reduce the generation of the microcracks. Accordingly, the presence of the voids 61 enables to reduce the damage exerted by the substrate removal on the GaN-containing structure 20.

After the LLO, the connection in the contact interface between the structure 20 and the base substrate 10 is mainly effected by Ga. Even an application of slight force enables to remove the base substrate 10 to yield the structure as shown in FIG. 6C.

Next, the Ga and the like attached to the surface of the structure 20 are removed. For that purpose, washing with diluted hydrochloric acid is conducted.

Next, the depressed portions 47 of the first nitride semiconductor layer shown in FIG. 6C are removed. In the depressed portions 47, the damage due to the LLO still remains.

The depth of this damage layer is about 500 nm. As the method for removing the depressed portions 47, Ar ion milling is used.

Next, as shown in FIG. 6D, the surface of the first nitride semiconductor layer 40 is planarized and at the same time the film thickness of the first nitride semiconductor layer 40 is adjusted.

In this case, Ar ion milling and GCIB etching are used in combination.

In particular, GCIB is effective in the planarization. Finally, the surface of the first nitride semiconductor layer 40 is washed with diluted hydrochloric acid.

Thus, the nitride semiconductor-containing structure 20 with a flat underside is obtained.

According to the method of present Example, the nitride semiconductor-containing structure of the present invention is enabled.

### Example 5

In Example 5, an application example of the nitride semiconductor-containing composite substrates described in the embodiments and Examples of the present invention is described.

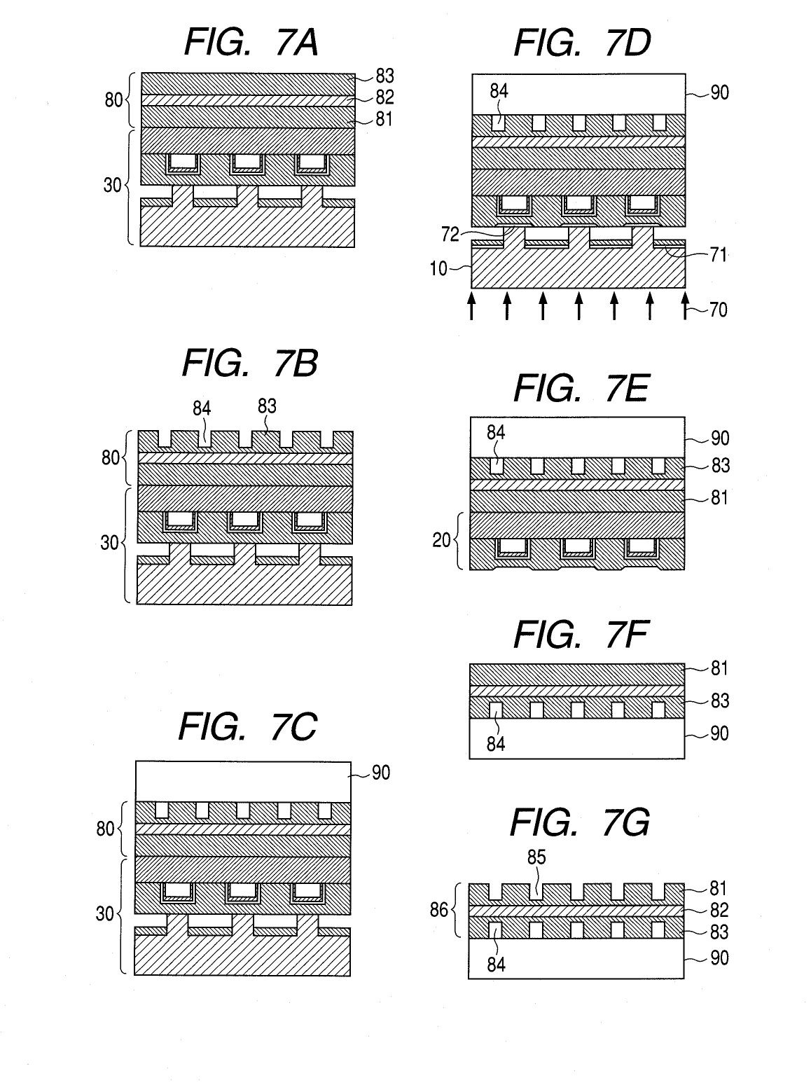

FIGS. 7A to 7G show the schematic sectional views for illustrating the application example of the nitride semiconductor-containing composite substrates described in the embodiments and Examples of the present invention.

First, the nitride semiconductor-containing composite substrate 30 described in the second embodiment and Example 2 is produced. The production method of the composite substrate 30 has already been described in the third embodiment and Example 3, and hence the description thereof is omitted.

Next, as shown in FIG. 7A, a nitride semiconductor-containing device structure layer 80 is formed by using the composite substrate 30 as a substrate.

The formation method of the device structure layer 80 is the heretofore known MOCVD method. With respect to the formation conditions, the heretofore known conditions may be consulted. No redundant description of the formation conditions is made herein.

The device structure layer 80 is formed of, for example, a nitride semiconductor layer 81 as a first layer, a nitride semiconductor layer 82 as a second layer and a nitride semiconductor layer 83 as a third layer.

The structure and composition of each of the layers are as follows:

81: 160-nm n-type Al_{0.1}Ga_{0.9}N

82: A multi-quantum well of InGaN without introduction of impurities, being formed of 3-nm In_{0.08}Ga_{0.92}N/15-nm In_{0.01}Ga_{0.99}N/3-nm In_{0.08}Ga_{0.92}N

83: 160-nm p-type Al_{0.1}Ga_{0.9}N

Next, as shown in FIG. 7B, a first asperity structure 84 is formed on the p-type AlGaN represented by the nitride semiconductor layer 83 as the third layer.

The first asperity structure is, for example, a triangular lattice structure formed of circular holes of 100 nm in diameter, 70 nm in depth and 160 nm in period. The production of the first asperity structure is conducted with the heretofore known technique.

For example, a resist pattern is formed by the electron beam exposure method, and the exposed portion of the nitride semiconductor layer 83 as the third layer is etched with the resist pattern as a mask by using the RIE method using a mixed gas including Cl₂, BCl₃ and the like to form the first asperity structure 84. The first asperity structure 84 is a so-called two-dimensional photonic crystal.

Next, as shown in FIG. 7C, the nitride semiconductor layer 83 as the third layer with the first asperity structure 84 formed thereon is bonded to a lamination substrate 90. In this case, the bonding is conducted by a substrate junction method including a surface activation step and a heating-pressurizing step of the substrate.

A set of substrate junction conditions are such that temperature is about 400° C. and the load is about 0.5 MPa.

Next, as shown in FIG. 7D, the base substrate 10 is removed by the LLO method described in the fourth embodiment and Example 4.

FIG. 7E shows the condition after the base substrate 10 has been removed.

Next, as shown in FIG. 7E, the section of the nitride semiconductor-containing structure 20 is removed while the planarization is being conducted by using in combination the Ar ion milling and the GCIB etching. As shown in FIG. 7F, the removal of the section of the structure 20 exposes the nitride semiconductor layer 81 as the first layer to yield a structure shown in FIG. 7F. For the convenience of visibility, FIG. 7F shows a structure after the removal of the section of the structure 20 in an upside-down manner.

Next, as shown in FIG. 7G, a second asperity structure 85 is formed on the n-type AlGaN represented by the nitride semiconductor layer 81 as the first layer to yield a nitride semiconductor-containing device structure 86.

When the second asperity structure 85 is a periodic asperity pattern, the second asperity structure 85 is a so-called two-dimensional photonic crystal.

The pattern shape of the second asperity structure 85 may be appropriately designed with respect to the structure thereof according to the intended purpose.

The second asperity structure 85 may be exactly the same in structure as the first asperity structure 84. As shown in FIG. 7G, as viewed along the direction normal to the top face of the nitride semiconductor layer 81 as the first layer, the holes of the second asperity structure 85 may roughly overlap in position with the holes of the first asperity structure 84.

The nitride semiconductor-containing device structure 86 produced by the above-described method can be applied, for example, to lasers.

In such a case, the nitride semiconductor layer 82 as the second layer serves as an active layer. A laser oscillation is possible with the second asperity structure 85 as a two-dimensional photonic crystal and the first asperity structure 84 as another two-dimensional photonic crystal respectively formed on the nitride semiconductor layer 81 as the first layer and the nitride semiconductor layer 83 as the third layer.

When the electrodes are not formed as in FIG. 7G, the nitride semiconductor-containing device structure 86 can be made to laser-oscillate by photoexcitation.

When the nitride semiconductor-containing device structure 86 is made to laser-oscillate by current injection, electrodes may be further formed. For example, as a lamination substrate 90, a p-type low-resistance Si substrate is used.

In such a case, the p-electrode can be formed on the Si side. On the other hand, the n-electrode may be formed in the upper portion of the first nitride semiconductor layer 81 such as the portion free from the second asperity structure 85 as a two-dimensional photonic crystal.

In this Example, a production method of a limited structure has been presented.

However, by using the above-described method or the method easily assumable from the above-described method, there can be produced the structures modified in the factors such as the film composition (the material type, the thicknesses of the respective layers and the like) of the nitride semiconductor-containing device structure layer 80 and the structure (the type and period of the asperity pattern, the shape, size and depth of the holes of the asperity pattern) of each of the first asperity structure 84 and the second asperity structure 85.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-136290, filed May 26, 2008, which is hereby incorporated by reference herein in its entirety.

1. A nitride semiconductor layer-containing structure, comprising a laminated structure that includes at least two nitride semiconductor layers, wherein
between the two nitride semiconductor layers in the laminated structure are a plurality of voids surrounded by faces of walls inclusive of inner walls of recessed portions of an asperity pattern formed on a nitride semiconductor layer that is a lower layer of the two nitride semiconductor layers, and
crystallinity defect-containing portions to suppress a lateral growth of the nitride semiconductor layer are formed on at least part of the inner walls of the recessed portions to form the voids.

2. A nitride semiconductor layer-containing structure according to claim 1, wherein the structure is arranged on a base substrate so as to form a composite substrate.

3. A nitride semiconductor layer-containing structure according to claim 2, further comprising, between the base substrate and the nitride semiconductor layer that is the lower layer of the two nitride semiconductor layers, a plurality of voids surrounded by faces of walls inclusive of inner walls of recessed portions of an asperity pattern formed on the nitride semiconductor layer that is the lower layer.

4. A nitride semiconductor layer-containing structure according to claim 2, wherein the base substrate is a single crystal substrate.

5. A nitride semiconductor layer-containing structure according to claim 2, wherein the base substrate is a single crystal substrate on which an intermediate film that is homogeneous or heterogeneous to the single crystal substrate is formed.

6. A nitride semiconductor layer-containing structure according to claim 2, wherein a material of the single crystal substrate is any of a nitride semiconductor, sapphire, silicon (Si), and silicon carbide (SiC).

7. A production method of a nitride semiconductor layer-containing composite substrate, comprising:
a first step of forming a first nitride semiconductor layer on a base substrate;
a second step of forming an asperity pattern on the first nitride semiconductor layer;
a third step of forming crystallinity defect-containing portions, due to a state modified from a single crystal state, on at least part of inner walls of recessed portions in the asperity pattern on the first nitride semiconductor layer; and
a fourth step of forming a second nitride semiconductor layer on the asperity pattern formed on the first nitride semiconductor layer and including the crystallinity defect-containing portions.

8. The production method of the composite substrate according to claim 7, wherein the first step includes forming a continuous layer of the first nitride semiconductor by forming an asperity pattern on a base substrate and by conducting an epitaxial lateral over-growth of a nitride semiconductor layer on that asperity pattern on the base substrate.

9. The production method of the composite substrate according to claim 7, wherein the fourth step includes forming a continuous layer of the second nitride semiconductor by conducting an epitaxial lateral over-growth of a nitride semiconductor layer.

10. The production method of the composite substrate according to claim 7, wherein, after the fourth step has been conducted once, the second step and the fourth step are respectively repeated N times (N≧0), and the third step is repeated M times (M≦N).

11. A production method of the composite substrate according to claim 7, further comprising a step of removing a base substrate from the composite substrate to form a nitride semiconductor layer-containing structure.

12. The production method of the composite substrate according to claim 11, wherein the step of removing the base substrate includes performing selective etching or polishing.

13. The production method of the composite substrate according to claim 11, wherein the base substrate is a single crystal substrate on which an intermediate film that is homogeneous or heterogeneous to the single crystal substrate is formed, and the intermediate film is removed by the selective etching.

14. The production method of the composite substrate according to claim 11, wherein the step of removing the base substrate is a step in which:
sapphire is used for the base substrate and a laser irradiation is conducted from a side of the base substrate; and
the first nitride semiconductor layer is decomposed at an interface between the sapphire substrate and the nitride semiconductor layer-containing structure.

15. The production method of the composite substrate according to claim 11, wherein the base substrate is a single crystal substrate on which an intermediate film that is homogeneous or heterogeneous to the single crystal substrate is formed, and the intermediate film of the base substrate is selectively removed by a photoelectrochemical etching.

16. The production method of the composite substrate according to claim 11, wherein the step of removing the base substrate includes bonding the nitride semiconductor layer-containing structure to a second substrate and then removing the base substrate.
